(19) United States
(12) Patent Application Publication
(10) Pub. No.: US 2025/0345882 A1
(43) Pub. Date: Nov. 13, 2025

(54) AIR CURTAIN APPARATUS AND WAFER CUTTER INCLUDING THE SAME

(71) Applicant: SAMSUNG ELECTRONICS CO., LTD., Suwon-si (KR)

(72) Inventors: Youngkook CHO, Suwon-si (KR); Kyungsoon PARK, Suwon-si (KR); Youngmin CHOI, Suwon-si (KR); Namtae HEO, Suwon-si (KR)

(73) Assignee: SAMSUNG ELECTRONICS CO., LTD., Suwon-si (KR)

(21) Appl. No.: 18/927,487

(22) Filed: Oct. 25, 2024

(30) Foreign Application Priority Data
May 7, 2024 (KR) 10-2024-0059924

(51) Int. Cl. B23K 26/142; B23K 26/06; B23K 26/14

(52) U.S. Cl. CPC B23K 26/142; B23K 26/0648; B23K 26/1438

(57) ABSTRACT

An air curtain apparatus may include a blowing block including a main blowing passage and an auxiliary blowing passage. The blowing block may receive compressed air. The main blowing passage may be configured to blow a first portion of the compressed air between an object (e.g., a lens) and another object (e.g., a wafer). The auxiliary blowing passage may be above the main blowing passage and configured to blow a second portion of the compressed air onto the object. Thus, contaminants may be inhibited from contaminating the object.

### CROSS-REFERENCE TO RELATED APPLICATION

This application claims priority under 35 USC § 119 to Korean Patent Application No. 10-2024-0059924, filed on May 7, 2024, in the Korean Intellectual Property Office (KIPO), the contents of which are herein incorporated by reference in their entirety.

### BACKGROUND

### 1. Field

Example embodiments of the present disclosure relate to an air curtain apparatus and a wafer cutter including the same. More specifically, example embodiments of the present disclosure relate to an apparatus for forming an air curtain between a lens, which may be configured to focus a laser onto a wafer for cutting the wafer, and the wafer, and a wafer cutter including the air curtain apparatus.

### 2. Description of Related Art

Generally, a wafer may be cut using a wafer cutter. The wafer cutter may include a laser irradiator and an air curtain apparatus. The laser irradiator may irradiate a laser onto the wafer. The laser irradiator may include a lens configured to focus the laser onto a scribe lane of the wafer. The air curtain apparatus may blow compressed air between the lens and the wafer to form an air curtain that may prevent contaminants from adhering to the lens.

According to a comparative embodiment, the air curtain apparatus may include a plurality of blowing holes through which compressed air may be blown. However, the compressed air blown from the blowing holes may not cover the entire lens such that the lens may be contaminated with contaminants. The contamination of the lens may reduce power of the laser. Therefore, in comparative embodiments, additional processes for cleaning the lens may be required such that operating efficiency of the wafer cutter may be reduced.

### SUMMARY

Example embodiments of the present disclosure provide an air curtain apparatus configured to prevent contaminants from getting on a lens.

Example embodiments of the present disclosure also provide a wafer cutter including the air curtain apparatus.

According to example embodiments of the present disclosure, a system may be provided and include: a lens; and an air curtain apparatus including a blowing block configured to receive compressed air and including: a main blowing passage configured to blow a first portion of the compressed air toward the lens; and an auxiliary blowing passage above the main blowing passage and configured to blow a second portion of the compressed air onto the lens.

According to example embodiments of the present disclosure, an air curtain apparatus may be provided and include: a blowing block including a blowing surface configured to blow compressed air onto an object in a case where the blowing block is below the object, the blowing surface being curved about a vertical direction, wherein the blowing block further includes: a main blowing passage that extends along a first horizontal direction to the blowing surface, and is configured to blow a first portion of the compressed air along the first horizontal direction toward the object; and an auxiliary blowing passage that extends, above the main blowing passage, along an inclined direction upwardly to the blowing surface and is configured to blow a second portion of the compressed air along the inclined direction toward the object.

According to example embodiments of the present disclosure, a wafer cutter may be provided and include: a laser irradiator configured to be arranged over a wafer to irradiate a laser onto the wafer, the laser irradiator including a lens configured to focus the laser onto the wafer; and an air curtain apparatus configured to form an air curtain using compressed air between the lens and the wafer, wherein the air curtain apparatus includes a blowing block configured to receive the compressed air, the blowing block including: a main blowing passage configured to blow a first portion of the compressed air between the lens and the wafer; and an auxiliary blowing passage above the main blowing passage and configured to blow a second portion of the compressed air onto the lens.

According to example embodiments of the present disclosure, since the main blowing passage may have a unitary structure formed along the horizontal direction in the blowing block, the compressed air blown through the main blowing passage may cover the entire lens. In particular, the compressed air from the auxiliary blowing passage over the main blowing passage may be blown toward the lens along an inclined direction so that the air curtain may be uniformly formed between the lens and the wafer. Thus, contaminants may be inhibited from contaminating the lens, which may prevent the laser from degrading in power. Furthermore, additional processes for lens cleaning may not be required, which may improve operating efficiency of the wafer cutter.

### BRIEF DESCRIPTION OF DRAWINGS

Example embodiments of the present disclosure will be more clearly understood from the following detailed description taken in conjunction with the accompanying drawings. FIGS. 1 to 10 represent non-limiting example embodiments of the present disclosure as described herein.

FIG. 1 is a cross-sectional view illustrating a wafer cutter in accordance with example embodiments;

FIG. 2 is a perspective view illustrating an air curtain apparatus of the wafer cutter shown in FIG. 1;

FIG. 3 is a front view illustrating the air curtain apparatus shown in FIG. 2;

FIG. 4 is an enlarged cross-sectional view illustrating a main blowing passage and an auxiliary blowing passage of the air curtain apparatus shown in FIG. 3;

FIG. 5 is a view illustrating an air curtain formed between a lens and a wafer by compressed air blown through the main blow passage and the auxiliary blow passage shown in FIG. 4;

FIG. 6 is a perspective view illustrating an air curtain apparatus in accordance with example embodiments;

FIG. 7 is a front view illustrating the air curtain apparatus shown in FIG. 6;

FIG. 8 is a perspective view illustrating an air curtain apparatus in accordance with example embodiments;

FIG. 9 is a front view illustrating the air curtain apparatus shown in FIG. 8; and

FIG. 10 is a perspective view illustrating an air curtain apparatus in accordance with example embodiments.

### DETAILED DESCRIPTION

Hereinafter, non-limiting example embodiments of the present disclosure will be described in detail with reference to the accompanying drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

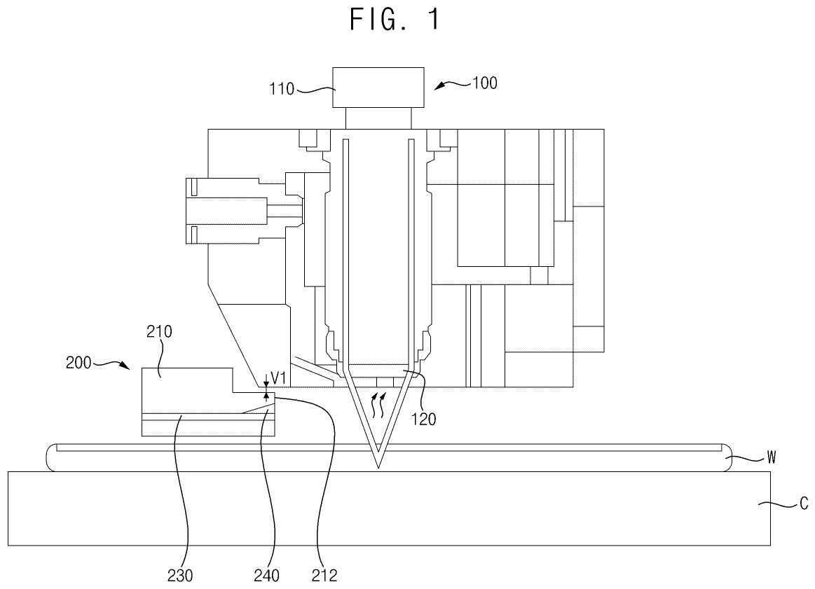

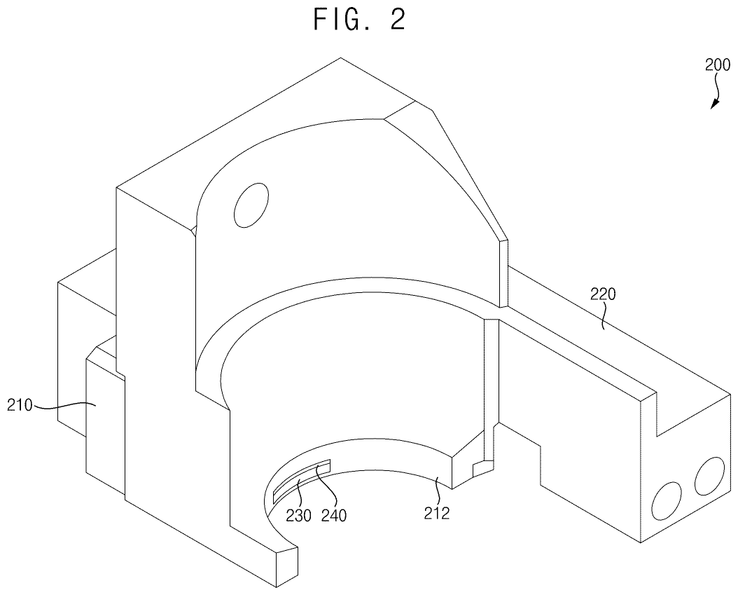

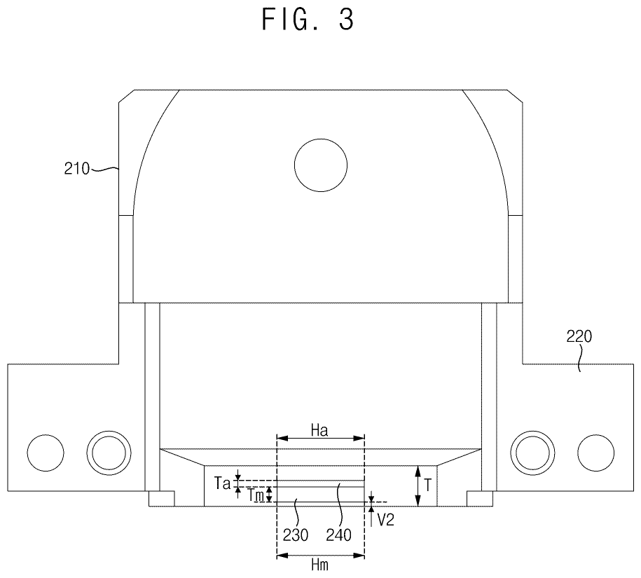

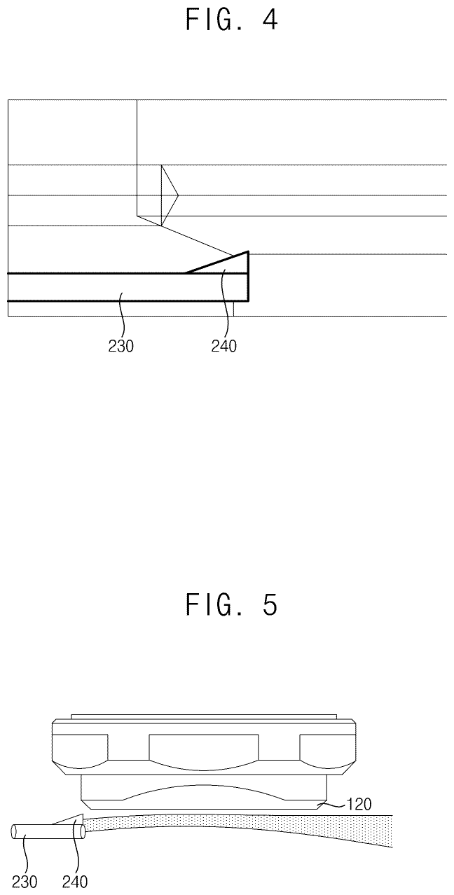

FIG. 1 is a cross-sectional view illustrating a wafer cutter in accordance with example embodiments, FIG. 2 is a perspective view illustrating an air curtain apparatus of the wafer cutter shown in FIG. 1, FIG. 3 is a front view illustrating the air curtain apparatus shown in FIG. 2, and FIG. 4 is an enlarged cross-sectional view illustrating a main blowing passage and an auxiliary blowing passage of the air curtain apparatus shown in FIG. 3.

Referring to FIGS. 1 to 4, a wafer cutter according to example embodiments may include a laser irradiator 100 and an air curtain apparatus 200.

The laser irradiator 100 may be disposed over a wafer W resting on a chuck table C. The laser irradiator 100 may include a laser source 110, a lens 120, and the like. The laser source 110 may be disposed over the wafer W to generate a laser. The lens 120 may be disposed between the laser source 110 and the wafer W to focus the laser generated by the laser source 110 onto a scribe lane of the wafer W.

The air curtain apparatus 200 may be disposed between the laser irradiator 100 and the wafer W. In particular, the air curtain apparatus 200 may be disposed below a side portion of the laser irradiator 100. The air curtain apparatus 200 may blow compressed air into a space between the lens 120 and the wafer W to form an air curtain between the lens 120 and the wafer W. The air curtain may prevent contaminants from getting on an object (e.g., the lens 120).

In example embodiments, the air curtain apparatus 200 may include a blowing block 210, a main blowing passage 230 and an auxiliary blowing passage 240.

The blowing block 210 may receive the compressed air. Thus, the blowing block 210 may be connected to a compressed air tank configured to store the compressed air. The blowing block 210 may be connected to the laser irradiator 100 by a connection block 220.

In example embodiments, the blowing block 210 may include a blowing surface 212 configured to blow the compressed air. The blowing surface 212 may face the space between the lens 120 and the wafer W. In particular, the blowing surface 212 may have a curved shape around a vertical direction. For example, the blowing surface 212 may have a roughly semi-circular shape configured to surround the space between the lens 120 and the wafer W, but is not limited to.

In example embodiments, the blowing surface 212 may be located below the lens 120. In particular, a vertical length V1 between an upper end of the blowing surface 212 and a lower surface of the lens 120 may be greater than, but not limited to, about 1 mm.

The main blowing passage 230 may be formed in the blowing surface 212 of the blowing block 210. In example embodiments, the main blowing passage 230 may be a single passage extending through the blowing block 210, to the blowing surface 212, along a horizontal direction. The compressed air in the blowing block 210 may be blown along the horizontal direction toward the space between the lens 120 and the wafer W through the main blowing passage 230. As such, since the main blowing passage 230 has a unitary structure, a sufficient amount of the compressed air may be blown along the horizontal direction through the main blowing passage 230. As a result, the air curtain formed by the compressed air may cover the entire lower surface of the lens 120 to suppress the lens 120 from being contaminated.

In example embodiments, a thickness Tm of the main blowing passage 230 may be, but is not limited to, about 50% or less of a thickness T of the blowing surface 212. When the thickness Tm of the main blowing passage 230 exceeds about 50% of the thickness T of the blowing surface 212, vortices may be generated in the compressed air blown through the main blowing passage 230, so that the air curtain may not be uniformly formed in the space between the lens 120 and the wafer W. Therefore, the thickness Tm of the main blowing passage 230 may be set to about 50% or less of the thickness T of the blowing surface 212 to suppress vortices. For example, when the thickness T of the blowing surface 212 is about 2 mm, the thickness Tm of the main blowing passage 230 may be about 1 mm or less.

Further, a vertical length V2 between a lower end of the main blowing passage 230 and a lower end of the blowing surface 212 may be, but is not limited to, about 25% or less of the thickness T of the blowing surface 212. In other words, the main blowing passage 230 may be located in a lower region in a total region of the blowing surface 212. For example, when the thickness T of the blowing surface 212 is about 2 mm, the vertical length V2 between the lower end of the main blowing passage 230 and the lower end of the blowing surface 212 may be about 0.5 mm or less.

The auxiliary blowing passage 240 may be disposed over the main blowing passage 230. That is, the auxiliary blowing passage 240 may be formed in the blowing surface 212 over the main blowing passage 230. Thus, the auxiliary blowing passage 240 may be connected to the main blowing passage 230. That is, a lower surface of the auxiliary blowing passage 240 may correspond to a portion of the upper surface of the main blowing passage 230. An upper surface of the auxiliary blowing passage 240 may have an upwardly sloping structure. Alternatively, the auxiliary blowing passage 240 may have an independent structure that may not be connected to the main blowing passage 230.

In example embodiments, the lower surface of the auxiliary blowing passage 240 and the upper surface of the main blowing passage 230 may be surfaces of a same inner wall of the blowing block 210, but embodiments of the present disclosure are not limited thereto.

In example embodiments, the auxiliary blowing passage 240 may be in communication with main blowing passage 230, such that the auxiliary blowing passage 240 receives a portion of the compressed air from the main blowing passage 230 and blows the portion of the compressed air out from a distal end of the auxiliary blowing passage 240 (e.g., an end of the auxiliary blowing passage 240 within the blowing surface 212. For example, an end of the auxiliary blowing passage 240, furthest from the blowing surface 212, may be in communication with an upper portion of the main blowing passage 230.

In example embodiments, the auxiliary blowing passage 240 extends along an upwardly inclined direction, allowing the compressed air to be blown along the inclined direction. In other embodiments, the auxiliary blowing passage 240 may not have an inclined structure. As such, since the compressed air may be blown along the horizontal direction through the main blowing passage 230 and along the inclined direction through the auxiliary blowing passage 240, the air curtain may have a strong pressure to better suppress the lens 120 from being contaminated.

In example embodiments, a horizontal length Ha of the auxiliary blowing passage 240 may be the same as a horizontal length Hm of the main blowing passage 230, but is not limited thereto. For example, when the horizontal length Hm of the main blowing passage 230 is about 7 mm, the horizontal length Ha of the auxiliary blowing passage 240 may also be about 7 mm. In other embodiments, the horizontal length Ha of the auxiliary blowing passage 240 may be shorter than the horizontal length Hm of the main blowing passage 230.

Further, the horizontal length Hm of the main blowing passage 230 and the horizontal length Ha of the auxiliary blowing passage 240 may be shorter than a diameter of the lens 120, but are not limited to. When the horizontal length Hm of the main blowing passage 230 and the horizontal length Ha of the auxiliary blowing passage 240 are equal to or longer than the diameter of the lens 120, the compressed air blown from the main blowing passage 230 and the auxiliary blowing passage 240 may escape the lens 120. Accordingly, the horizontal length Hm of the main blowing passage 230 and the horizontal length Ha of the auxiliary blowing passage 240 may be set to be shorter than the diameter of the lens 120.

In example embodiments, a thickness Ta of the auxiliary blowing passage 240 may be about 50% or less of the thickness Tm of the main blowing passage 230, but is not limited thereto. For example, when the thickness Tm of the main blowing passage 230 is about 1 mm, the thickness Ta of the auxiliary blowing passage 240 may be about 0.5 mm or less.

FIG. 5 is a view illustrating an air curtain formed between the lens and the wafer by the compressed air blown through the main blowing passage and the auxiliary blowing passage shown in FIG. 4.

As shown in FIG. 5, it can be noted that the air curtain formed by the compressed air blown through the main blowing passage 230 and the auxiliary blowing passage 240 may be uniformly distributed between the lens 120 and the wafer W.

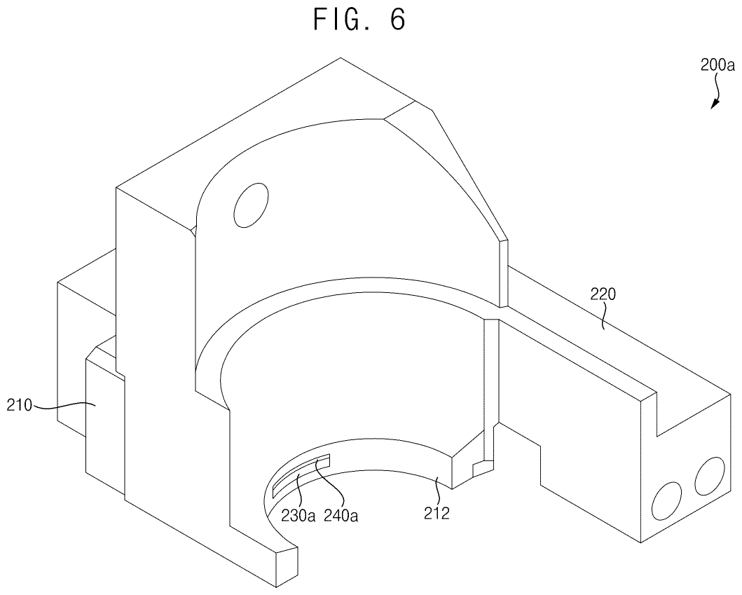

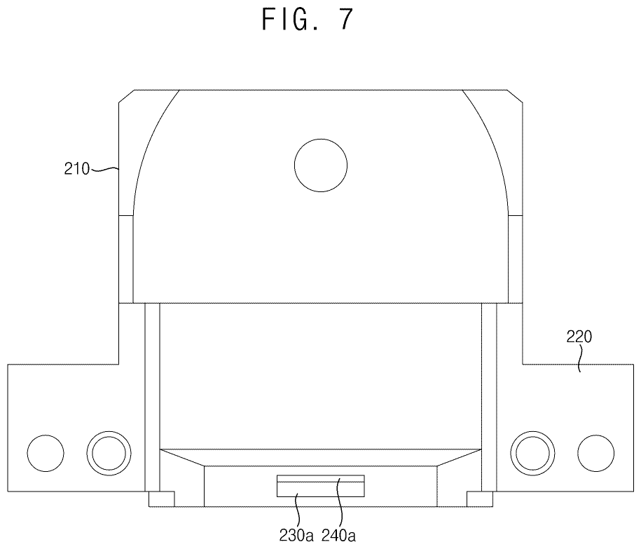

FIG. 6 is a perspective view illustrating an air curtain apparatus in accordance with example embodiments, and FIG. 7 is a front view illustrating the air curtain apparatus shown in FIG. 6.

The air curtain apparatus 200a of this embodiment may include substantially the same elements as the elements of the air curtain apparatus 200 shown in FIG. 2, except for a location of a main blowing hole and an auxiliary blowing hole. Accordingly, identical elements may be denoted by the same reference numerals, and repetitive descriptions of identical elements may be omitted.

Referring to FIGS. 6 and 7, a main blowing passage 230a and an auxiliary blowing passage 240a of example embodiments may be formed in a middle region of the blowing surface 212. Since structures of the main blowing passage 230a and the auxiliary blowing passage 240a may be substantially the same as the structures of the main blowing passage 230 and the auxiliary blowing passage 240 shown in FIG. 2, a repeated description of the main blowing passage 230a and the auxiliary blowing passage 240a may be omitted.

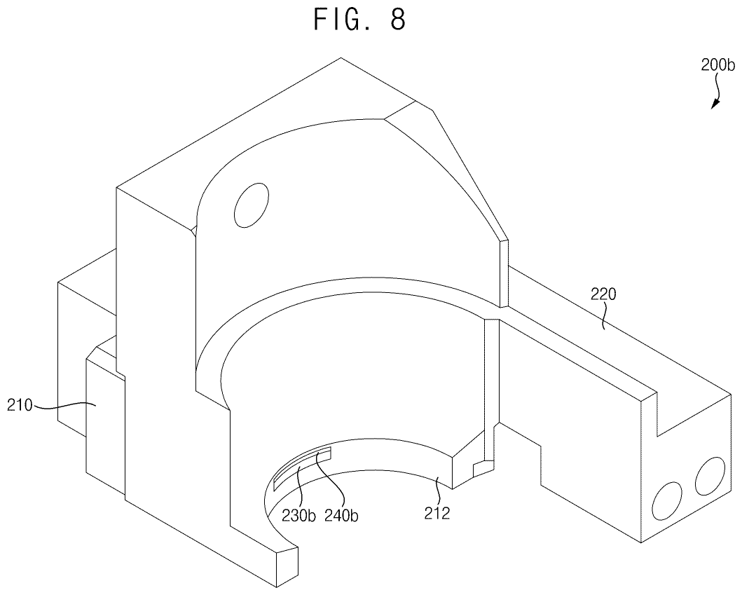

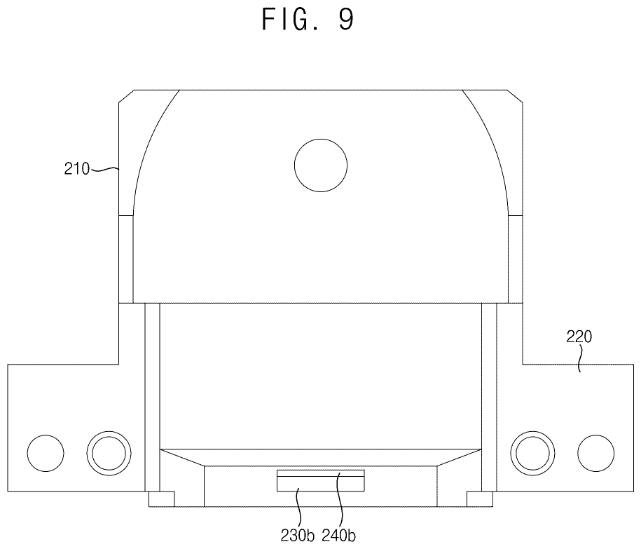

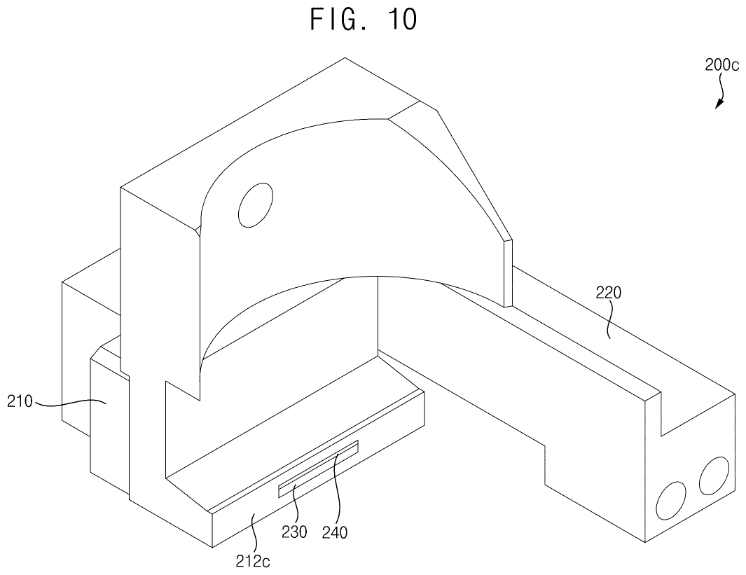

FIG. 8 is a perspective view illustrating an air curtain apparatus in accordance with example embodiments, and FIG. 9 is a front view illustrating the air curtain apparatus shown in FIG. 8.

The air curtain apparatus 200b of this embodiment may include substantially the same elements as the elements of the air curtain apparatus 200 shown in FIG. 2, except for a location of a main blowing hole and an auxiliary blowing hole. Accordingly, identical elements may be denoted by the same reference numerals, and repetitive descriptions of identical elements may be omitted.

Referring to FIGS. 8 and 9, a main blowing passage 230b and an auxiliary blowing passage 240b of example embodiments may be formed in an upper region of the blowing surface 212. Since structures of the main blowing passage 230b and the auxiliary blowing passage 240b may be substantially the same as the structures of the main blowing passage 230 and the auxiliary blowing passage 240 shown in FIG. 2, repeated descriptions of the main blowing passage 230b and the auxiliary blowing passage 240b may be omitted.

FIG. 10 is a perspective view illustrating an air curtain apparatus in accordance with example embodiments.

The air curtain apparatus 200c of this embodiment may include substantially the same elements as the elements of the air curtain apparatus 200 shown in FIG. 2, except for a blowing surface. Accordingly, identical elements may be denoted by the same reference numerals, and repetitive descriptions of identical elements may be omitted.

Referring to FIG. 10, a blowing surface 212c of example embodiments may have a flat shape rather than a curved shape. The main blowing passage 230 and the auxiliary blowing passage 240 may be formed in the blowing surface 212c that has the flat shape.

According to example embodiments, the main blowing passage 230 may have the unitary structure formed along the horizontal direction in the blowing block 210, so that the compressed air blown through the main blowing passage 230 may cover the entire lens 120. In particular, the compressed air from the auxiliary blowing passage 240 over the main blowing passage 230 may be blown at the inclined angle towards the lens 120, so that the air curtain may be uniformly formed between the lens 120 and the wafer W. Thus, the contaminants may be inhibited from contaminating the lens 120, thereby preventing the power degradation of the laser. Furthermore, additional processes for cleaning the lens 120 may not be required, which may improve the operating efficiency of the wafer cutter.

While non-limiting example embodiments of the present disclosure have been described with reference to the drawings, those skilled in the art will appreciate that various modifications and changes may be made to the example embodiments of the present disclosure without departing from the spirit and scope of the present disclosure.

What is claimed is:

1. A system comprising:
a lens; and
an air curtain apparatus comprising:
a blowing block configured to receive compressed air and including:
a main blowing passage configured to blow a first portion of the compressed air toward the lens; and
an auxiliary blowing passage above the main blowing passage and configured to blow a second portion of the compressed air onto the lens.

2. The air curtain apparatus of claim 1, wherein the blowing block further comprises a blowing surface in which the main blowing passage and the auxiliary blowing passage are formed.

3. The air curtain apparatus of claim 2, wherein the blowing surface is below the lens.

4. The air curtain apparatus of claim 3, wherein a vertical length between an upper end of the blowing surface and a lower surface of the lens is greater than or equal to 1 mm.

5. The air curtain apparatus of claim 3, wherein the blowing surface has a curved shape, about a vertical direction, or a flat shape.

6. The air curtain apparatus of claim 3, wherein the main blowing passage comprises a single passage extending along a first horizontal direction in the blowing block to the blowing surface, the single passage configured to blow the compressed air along the first horizontal direction.

7. The air curtain apparatus of claim 6, wherein a thickness of the main blowing passage in a vertical direction is less than or equal to 50% of a thickness of the blowing surface in the vertical direction.

8. The air curtain apparatus of claim 6, wherein a vertical length between a lower end of the main blowing passage and a lower end of the blowing surface is less than or equal to 25% of a thickness of the blowing surface.

9. The air curtain apparatus of claim 6, wherein the auxiliary blowing passage is connected to the main blowing passage.

10. The air curtain apparatus of claim 9, wherein the auxiliary blowing passage extends along an inclined direction upwardly to the blowing surface, and the auxiliary blowing passage is configured to blow the compressed air along the inclined direction.

11. The air curtain apparatus of claim 10, wherein a horizontal length of the auxiliary blowing passage in a second horizontal direction, that intersects the first horizontal direction, is equal to a horizontal length of the main blowing passage in the second horizontal direction.

12. The air curtain apparatus of claim 11, wherein the horizontal length of the main blowing passage and the horizontal length of the auxiliary blowing passage are both shorter than a diameter of the lens.

13. The air curtain apparatus of claim 10, wherein a thickness of the auxiliary blowing passage in a vertical direction is less than or equal to 50% of a thickness of the main blowing passage in the vertical direction.

14. An air curtain apparatus comprising:
a blowing block comprising a blowing surface configured to blow compressed air onto an object in a case where the blowing block is below the object, the blowing surface being curved about a vertical direction,
wherein the blowing block further includes:
a main blowing passage that extends along a first horizontal direction to the blowing surface, and is configured to blow a first portion of the compressed air along the first horizontal direction toward the object; and
an auxiliary blowing passage that extends, above the main blowing passage, along an inclined direction upwardly to the blowing surface and is configured to blow a second portion of the compressed air along the inclined direction toward the object.

15. The air curtain apparatus of claim 14, wherein the auxiliary blowing passage is connected to the main blowing passage.

16. The air curtain apparatus of claim 14, wherein a thickness of the main blowing passage in the vertical direction is less than or equal to 50% of a thickness of the blowing surface in the vertical direction, and
wherein a vertical length between a lower end of the main blowing passage and a lower end of the blowing surface is less than or equal to 25% of the thickness of the blowing surface.

17. The air curtain apparatus of claim 14, wherein a horizontal length of the auxiliary blowing passage in a second horizontal direction, intersecting the first horizontal direction, is equal to a horizontal length of the main blowing passage in the second horizontal direction.

18. The air curtain apparatus of claim 14, wherein a thickness of the auxiliary blowing passage in the vertical direction is less than or equal to 50% of the thickness of the main blowing passage in the vertical direction.

19. A wafer cutter comprising:
a laser irradiator configured to be arranged over a wafer to irradiate a laser onto the wafer, the laser irradiator comprising a lens configured to focus the laser onto the wafer; and
an air curtain apparatus configured to form an air curtain using compressed air between the lens and the wafer,
wherein the air curtain apparatus comprises a blowing block configured to receive the compressed air, the blowing block including:
a main blowing passage configured to blow a first portion of the compressed air between the lens and the wafer; and
an auxiliary blowing passage above the main blowing passage and configured to blow a second portion of the compressed air onto the lens.

20. The wafer cutter of claim 19, wherein the blowing block comprises a blowing surface in which the main blowing passage and the auxiliary blowing passage are formed,
wherein the main blowing passage comprises a single passage extending along a horizontal direction to the blowing surface, the single passage configured to blow the compressed air along the horizontal direction, and
wherein the auxiliary blowing passage extends along an inclined direction upwardly to the blowing surface, the auxiliary blowing passage configured to blow the compressed air along the inclined direction.
